(19) United States
(12) Patent Application Publication
(10) Pub. No.: US 2003/0020554 A1
(43) Pub. Date: Jan. 30, 2003

(54) Frequency divider capable of outputting pulse waves with a phase difference of 180 degrees

(76) Inventor: Yu-Wei Lin, Taipei (TW)

Correspondence Address: RABIN & CHAMPAGNE, PC, 1101 14TH STREET, NW, SUITE 500, WASHINGTON, DC, 20005, US

(21) Appl. No.: 10/173,647

(22) Filed: Jun. 19, 2002

(30) Foreign Application Priority Data
Jul. 25, 2001 (TW) 90118248

(51) Int. Cl. H03B 7/00

(52) U.S. Cl. 331/115

(57) ABSTRACT

The invention discloses a frequency divider capable of outputting a pulse with a phase difference of 180 degrees. It can output two pulse signals, which can have a precise reversed relation in phase to each other. The structure mainly includes a frequency dividing circuit, used to divide the clock in frequency. A first flip-flop at least includes one signal output terminal and a clock input terminal. The clock input terminal is used to receive the clock. Also and, an inverter is coupled to an output reversed signal terminal of the frequency dividing circuit, and is connected to an input at a signal input terminal of the flip-flop. The reversed signal in phase, after being divided in frequency and being reversed again by the inverter, is fed into the flip-flop and outputted when being triggered by the clock.

This application incorporates by reference of Taiwan application Serial No. 090118248, filed Jul. 25, 2001.

### BACKGROUND OF THE INVENTION

1. Field of the Invention

This invention is related to a frequency divider. More particularly, the invention is related to a signal output of a frequency divider in pulse wave by a phase difference of 180 degrees.

2. Description of Related Art

From the current aspect of integrated circuit technology in applications, some applications sometime will need a group of pulses, which have an equal distance between them, to serve as a sampling signal, such as a circuit for converting digital signals to analog signals, a circuit for reproducing the data pulses, and so on. For example, if a pulse signal with a frequency of 125 MHz is to be produced, in the practical design for the circuit, it usually uses a clock generating device to generate a pulse signal of 250 MHz, and then the pulse signal of 250 MHz is divided by 2 by a frequency dividing circuit, so as to produce a pulse signal of 125 MHz.

Thus, when it is used in the practical application, if a sequence of 10 pulse signals in 125 MHz with equal distance between the pulse signals is desired, the basic way to do it is that a phase-locked loop (PLL) circuit is first used to produce a pulse signal of 250 MHz. Then, a frequency dividing circuit is used to obtain the desired result. In this way, it can be achieved to have a better duty cycle. Referring to FIG. 1, it is a drawing, schematically illustrating the constitution of a pulse signal group. As shown in FIG. 1, the pulse signal group S is constituted of 10 pulse signals with 125 MHz. The way to constitute them is then taking out 5 pulse signals, having the same 250 MHz but with a gap distance of 0.8 ns, from the voltage-controlled oscillator (VCO) of the phase-locked loop circuit. After then, 5 needed pulse signals (125 MHz and having the gap distance of 0.8 ns) are first obtained through a frequency dividing circuit, and another 5 pulse signals are obtained by inverting the phase of the 5 needed pulse signals.

However, the signal with reversed phase usually is outputted from the inverter of the frequency dividing circuit. Referring to FIG. 2A and FIG. 2B, they are circuit and timing diagram, schematically illustrating the circuit of the conventional clock frequency dividing circuit for the pulse and the timing chart at the input/output terminal. As shown in FIG. 2A and FIG. 2B, due to the frequency dividing action on the clock CK through the D-type flip-flop 20, the signal P and its reversed signal P′ in phase are generated. But, the reversed signal P′ in phase is resulting from the signal P, which is connected to an inverter 10. As a result, when the two signals are outputted, then it exists a delay from the phase inverting gate as indicated by the marking numeral 22. Therefore, since it exists a phase distance between the signal P and the reversed signal P′ in phase, this will cause a skew for the constitution of the pulse signal group S. As a result, the gap distance cannot remain equal for the pulse signal group S.

### SUMMARY OF THE INVENTION

It is therefore an objective of the present invention to provide a frequency divider capable of outputting a pulse with a well-controlled phase difference of 180 degrees. When a signal in a phase and a signal in the reversed phase are obtained at the same time, it will not occur for the two signals with a time delay.

It is therefore another objective of the present invention to provide a frequency divider capable of outputting a pulse with a phase difference of 180 degrees. By making use of the result that the normal phase and the reversed phase were come out without time delay, so as to obtain the ideal pulse signal group.

In accordance with the foregoing and other objectives of the present invention, the invention provides a frequency divider capable of outputting a pulse with a phase difference of 180 degrees. The structure mainly includes a clock, a first flip-flop, at least one data input terminal, and a clock input terminal. The clock input terminal is used to receive the clock, and the output signal in reversed phase of the flip-flop is a feedback connection to its signal input terminal, so as to implement the frequency dividing function. As a result, the output will be the input clock divided by two in frequency. An inverter is inserted by connecting its input to the signal input terminal which is the place to which the reversed output signal of the first flip-flop is feedback. Also and, a second flip-flop has at least a data input terminal and a clock input terminal. The clock input terminal can also be used to receive the clock, and the data input terminal is coupled to the output terminal of the inverter. After the flip-flop has been triggered by the clock, a pulse signal would be generated with precise 180 degrees phase shift from the output of the first flip-flop.

### BRIEF DESCRIPTION OF DRAWINGS

The invention can be more fully understood by reading the following detailed description of the preferred embodiments, with reference made to the accompanying drawings, wherein:

FIG. 1 is a drawing, schematically illustrating the constitution of a pulse signal group;

FIG. 2A is circuit drawing, schematically illustrating the circuit of the conventional clock frequency dividing circuit;

FIG. 2B is a drawing, schematically illustrating the timing pulse chart at the input/output terminal of the conventional clock frequency dividing circuit;

FIGS. 3A and 3B are the drawings of circuit diagram, schematically illustrating the circuit according to one preferred embodiment of the present invention; and

FIGS. 4A and 4B are the drawings of circuit diagram, schematically illustrating the circuit according to further another preferred embodiment of the present invention.

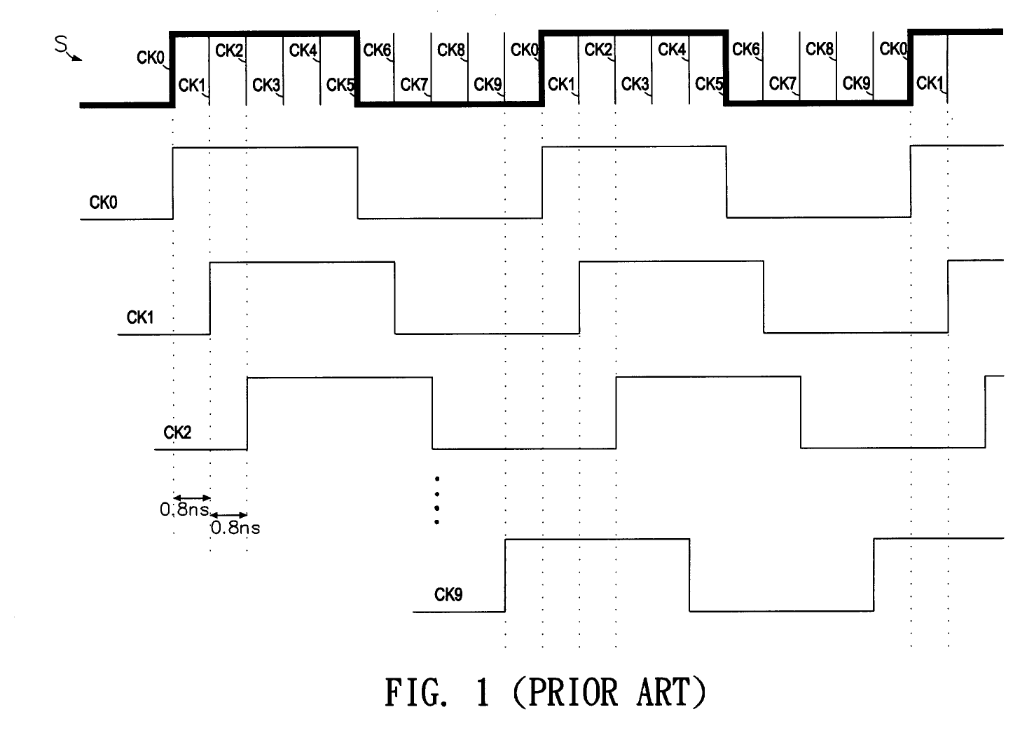

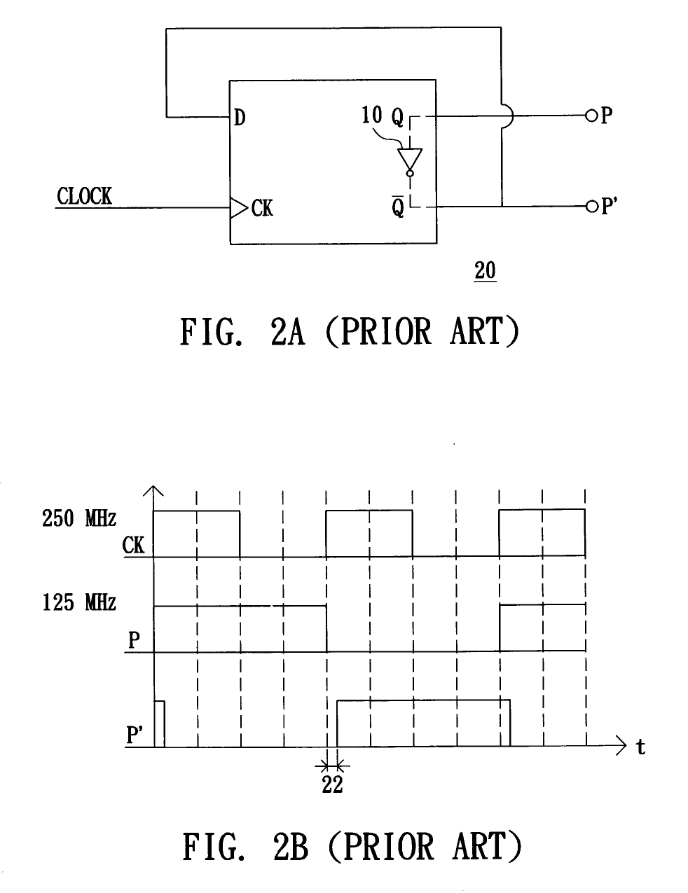

### DETAILED DESCRIPTION OF PREFERRED EMBODIMENTS

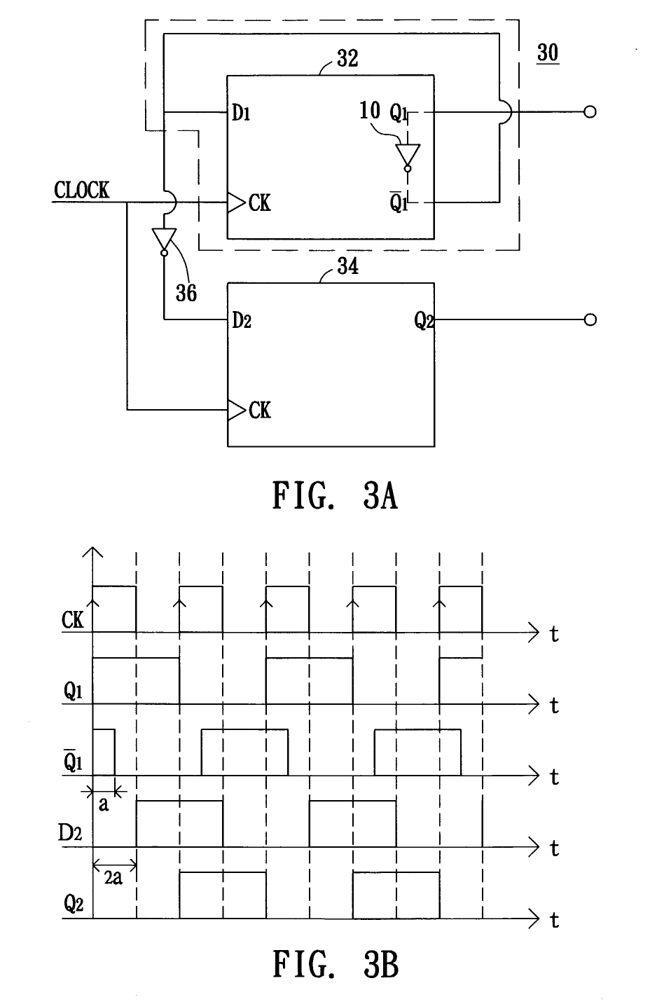

At the first, referring to FIG. 3A and FIG. 3B, they are drawings of the circuit structure and the output timing chart, according to one preferred embodiment of the present invention. As shown in the FIG. 3A and FIG. 3B, the clock is input to a first D-type flip-flop 32 and a second D-type flip-flop 34 at the same time, in which the frequency dividing circuit 30 makes use of the first D-type flip-flop 32 in operation. The first D-type flip-flop 32 has a signal input terminal D1 and a clock input terminal CK, and also has a signal output terminal Q1 and the another output terminal Q1. And, the second D-type flip-flop 34 has a signal input terminal D2 and a clock input terminal CK, and also has a signal output terminal Q2. Wherein, the signal output terminal Q1 of the first D-type flip-flop 32 is fed back to the signal input terminal D1 of the first D-type flip-flop 32. And, an inverter 36 is coupled between the first D-type flip-flop 32 and the second D-type flip-flop 34, that is, is connected to the signal input terminal D2 of the second D-type flip-flop 34. If the initial logic state for the signal output terminal Q1 of the first D-type flip-flop 32 is set to 1, then the another signal output terminal Q1 at this time has a signal with the logic state “0” after output through an inverting gate with a delay time. As marked by the reference mark a, the signal is fed back to the signal input terminal D1 of the first D-type flip-flop 32, and also goes through the inverter 36 and reaches to the signal input terminal D2 of the second D-type flip-flop 34. In this situation, it will be also delayed due to going through another inverting gate, as shown by the reference mark 2a. Then, the signal output terminal Q2 of the second D-type flip-flop 34 has outputted a signal with the logic state “0”. However, when the next clock CK causes the trigger, the logic state for the signal output terminal Q1 of the first D-type flip-flop 32 then changes to 0. At this moment, the another signal output terminal Q1 outputs a signal with the logic state “1” while going through an inverting gate with a delay. The signal is fed back to the signal input terminal D1 of the first D-type flip-flop 32, and also goes through the inverter 36 and reaches to the signal input terminal D2 of the second D-type flip-flop 34 at the same time. At this time, it is also delayed by the another inverting gate, and the signal out terminal Q2 of the second D-type flip-flop 34 then outputs a signal with the logic state “1”. As a result, as shown in FIG. 3B, since the two D-type flip-flop's have the similar structure, after the repeated action, it can be obtained for two clock signals, which are divided in frequency and has a phase difference of 180 degrees. Thus is achieved to have the ideal pulse signal group.

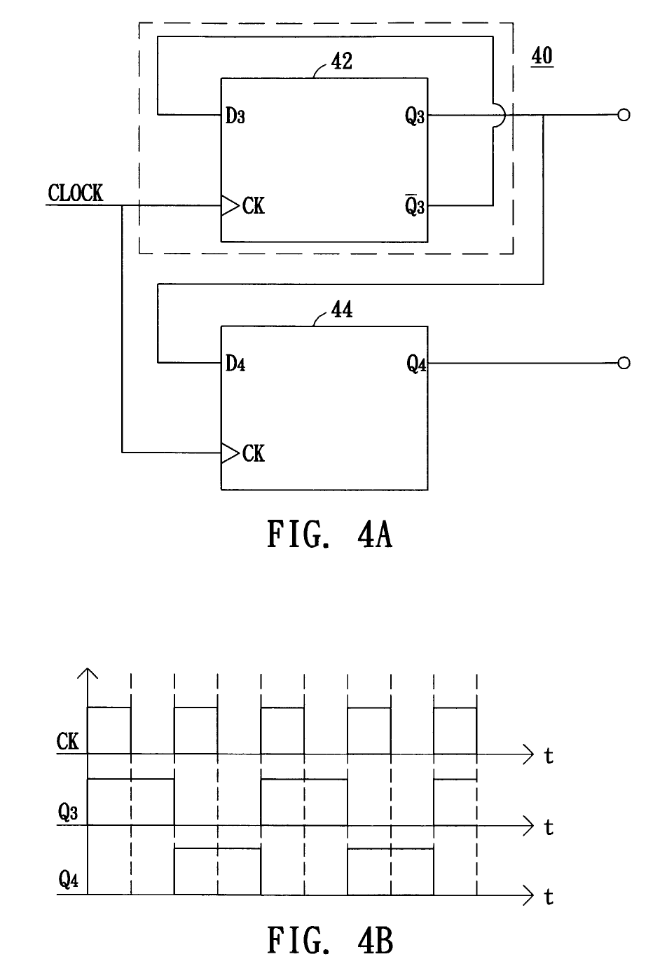

Referring to FIG. 4A and FIG. 4B, they are drawings of the circuit structure and the output timing chart, according to another preferred embodiment of the present invention. As shown in FIG. 4A, the third D-type flip-flop 42 is in operation for dividing the frequency, like the first D-type flip-flop 32 shown in FIG. 3A as the foregoing descriptions, and is a frequency dividing circuit 40. The third D-type flip-flop 42 has a signal input terminal D3 and a clock input terminal CK, and also has a signal output terminal Q3 and another signal output terminal Q3. The signal output terminal Q3 is fed back to the signal input terminal D3 of the third D-type flip-flop 42, and signal output terminal Q3 is connected to a fourth D-type flip-flop 44, in which it is coupled to the signal input terminal D4 of the fourth D-type flip-flop 44. The operation mode is also like the foregoing descriptions, that is, the signal output terminal Q3 and the signal output terminal Q3 are respectively set to have the logic states “0” and “1” as an example. Therefore, when a clock triggers these two flip-flops , the signal output terminal Q3 of the third D-type flip-flop 42 would output the divided frequency clock signal in normal phase. Due to the inversed logic state of signal input terminal D4 compared with signal input terminal D3, the signal output terminal Q4 of the fourth D-type flip-flop 44outputs the divided frequency clock signal in reversed phase until the next clock cycle . . . As a result, due to these two D-type flip-flops having the same structure (with the same circuit delay), after the repeated action, it can be obtained for two clock signals, which are divided in frequency and have a precise phase difference of 180 degrees. Thus it can be achieved to have the ideal pulse signal group.

In summary from the foregoing descriptions, the present invention provides a frequency divider capable of outputting a pulse with a phase difference of 180 degrees. The structure mainly includes a clock, a first flip-flop, at least one signal output terminal, and a clock input terminal. The clock input terminal is used to receive the clock, and the output signal in reversed phase of the flip-flop is a feedback connection to its signal input terminal, so as to produce the frequency dividing effect on the clock, and output the clock after being divided in frequency. An inverter is connected to the signal input terminal, where is the place to which the reversed output signal of the first flip-flop is feedback. Also and, a second flip-flop has at least a data input terminal and a clock input terminal. The clock input terminal can also be used to receive the clock, and the data input terminal is coupled to the output terminal of the inverter. After the second flip-flop has been triggered by the clock, a pulse signal would be generated with precise 180 degrees phase shift from the output of the first flip-flop..

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A frequency divider capable of outputting a pulse with a phase difference of 180 degrees, comprising:
a clock;
a frequency dividing circuit, used to divide said clock in frequency, and to generate a first signal divided in frequency and a second signal divided in frequency; and
an inverting device, which can receive said clock and is coupled to said frequency dividing circuit, so as to invert a phase of said second signal divided in frequency and output a third signal divided in frequency, wherein said third signal divided in frequency and said first signal divided in frequency have a precise phase difference of 180 degrees.

2. The frequency divider as recited in claim 1, wherein said second signal divided in frequency generated by said frequency dividing circuit has a distance with a specific phase difference to the first signal divided in frequency.

3. The frequency divider as recited in claim 1, wherein said frequency dividing circuit uses a first flip-flop in operation, said first flip-flop has at least a signal input terminal and a clock input terminal, and said second signal divide in frequency is connected in feedback to a signal input terminal, so as to produce said frequency dividing effect applied on said clock.

4. The frequency divider as recited in claim 3, wherein said first flip-flop can be one selected from said group consisting of a D-type flip-flop, a T-type flip-flop, a RS flip-flop, and a JK flip-flop.

5. The frequency divider as recited in claim 1, wherein said inverting device comprises:
a second flip-flop, having at least a signal input terminal and a clock input terminal, and said clock input terminal is also receiving said clock; and
an inverter, coupled to an output signal in reversed phase of said frequency dividing circuit, and also connected to a signal input terminal of said second flip-flop, wherein
said second signal divided in frequency of said frequency dividing circuit, after being reversed in phase by said inverter, is fed to said second flip-flop, and is outputted after being triggered by said clock.

6. The frequency divider as recited in claim 5, wherein said second flip-flop is similar to the first flip-flop.

7. A frequency divider capable of outputting a pulse with a phase difference of 180 degrees, comprising:
a clock;
a frequency dividing circuit, used to divide said clock in frequency, and to generate a first signal divided in frequency and a second signal divided in frequency; and
a flip-flop, having at least a signal input terminal and a clock input terminal, and wherein said signal input terminal is coupled to the first signal divided in frequency generated by said frequency dividing circuit, and said clock input terminal is used to receive said clock,
wherein after said first signal divided in frequency goes through said flip-flop, a third signal divided in frequency is outputted, said third signal divided in frequency has a precise phase difference of 180 degrees to the first signal divided in frequency.

8. The frequency divider as recited in claim 7, wherein said frequency dividing circuit said second signal divided in frequency generated by said frequency dividing circuit has a distance with a specific phase difference to the first signal divided in frequency.

9. The frequency divider as recited in claim 7, wherein said first flip-flop can be one selected from said group consisting of a D-type flip-flop, a T-type flip-flop, a RS flip-flop, and a JK flip-flop.

10. The frequency divider as recited in claim 7, wherein said frequency dividing circuit uses a flip-flop in operation, said flip-flop has at least a signal input terminal and a clock input terminal, and said second signal divide in frequency is connected in feedback to the signal input terminal, so as to produce said frequency dividing effect applied on said clock.

11. A frequency divider capable of outputting a pulse with a phase difference of 180 degrees, comprising:
a clock;
a first flip-flop, having at least a signal input terminal and a clock input terminal, and wherein said clock input terminal is used to receive said clock, and said first flip-flop can generate an output signal in normal phase, and an output signal in reversed phase, and said output signal in reversed phase is a connected in feedback to the signal input terminal;
an inverter, connected to the output signal in reversed phase of said first flip-flop; and
a second flip-flop, having at least a signal input terminal and a clock input terminal, and wherein said clock input terminal is used to receive said clock, and said signal input terminal is coupled to the inverter,
wherein said output signal in reversed phase outputted from said first flip-flop is fed to the second flip-flop through said inverter for inverting phase again, and a signal with a phase difference of 180 degrees to the signal in normal phase is generated after being triggered by said clock.

12. The frequency divider as recited in claim 11, wherein said first flip-flop and said second flip-flop can be one selected from said group consisting of a D-type flip-flop, a T-type flip-flop, a RS flip-flop, and a JK flip-flop.

13. The frequency divider as recited in claim 11, wherein said first flip-flop is similar to the second flip-flop.
